(19) United States
(12) Patent Application Publication
(10) Pub. No.: US 2024/0347537 A1
(43) Pub. Date: Oct. 17, 2024

(54) COMMON OUTPUT IN 3D STACK FET

(71) Applicant: Samsung Electronics Co., Ltd., Suwon-si (KR)

(72) Inventors: Mehdi Saremi, Danville, CA (US); Aravindh Kumar, Mountain View, CA (US); Ming He, San Jose, CA (US); Muhammed Ahosan Ul Karim, San Jose, CA (US); Rebecca Park, Mountain View, CA (US); Harsono Simka, Saratoga, CA (US)

(21) Appl. No.: 18/363,637

(22) Filed: Aug. 1, 2023

Related U.S. Application Data
(60) Provisional application No. 63/459,597, filed on Apr. 14, 2023.

(51) Int. Cl. H01L 27/092; H01L 21/02; H01L 21/8238; H01L 29/08

(52) U.S. Cl. CPC H01L 27/0922; H01L 21/02532; H01L 21/823807; H01L 29/0865; H01L 29/0882

(57) ABSTRACT

A method for manufacturing a semiconductor device according to one or more embodiments may include growing a first epitaxy layer at a first side and a second side of a stack of gates and channels, applying a sacrificial layer on the first epitaxy layer, growing a second epitaxy layer on the sacrificial layer, removing the sacrificial layer, and depositing a metal layer on the first epitaxy layer and the second epitaxy layer at the first side of the stack of gates and channels.

### CROSS-REFERENCE TO RELATED APPLICATION(S)

This application claims priority to and the benefit of U.S. Provisional Patent Application No. 63/459,597 filed on Apr. 14, 2023, which is incorporated herein by reference in its entirety.

### FIELD

The present application generally relates to stack transistors and processes for fabricating the same.

### BACKGROUND

Advances in semiconductor manufacturing technologies have resulted in field effect transistors (FETs) being manufactured in a three-dimensional stacked configuration known as 3D stack-FET (3DS-FET). In the 3DS-FET configuration, a metal-oxide semiconductor (MOS) is stacked on top of another MOS. However, such stacked configuration faces challenges that may ultimately result in undesirable higher parasitic resistance and capacitance.

### SUMMARY

According to one or more embodiments a method may include: growing a first epitaxy layer at a first side and a second side of a stack of gates and channels; applying a sacrificial layer on the first epitaxy layer; growing a second epitaxy layer on the sacrificial layer; removing the sacrificial layer; and depositing a metal layer on the first epitaxy layer and the second epitaxy layer at the first side of the stack of gates and channels.

The depositing of the metal layer on the first epitaxy layer and the second epitaxy layer may include depositing the metal layer between the first epitaxy layer and the second epitaxy layer.

The first epitaxy layer may include silicon germanium having a first concentration ratio of silicon to germanium, and the second epitaxy layer includes silicon.

The sacrificial layer may include silicon germanium having a second concentration ratio of silicon to germanium, which is different from the first concentration ratio of silicon to germanium for the first epitaxy layer.

The sacrificial layer may include a seeding layer for the growth of the second epitaxy layer.

The removing of the sacrificial layer may further include dry etching to selectively remove material having the second concentration ratio of silicon to germanium.

The first epitaxy layer may be an n-type material and the second epitaxy layer is a p-type material.

The first epitaxy layer may be a p-type material and the second epitaxy layer is an n-type material.

According to one or more embodiments, a semiconductor device may including: a first stack of gates and channels between a first side of a first epitaxy layer and a second side of the first epitaxy layer; a second stack of gates and channels on the first stack of gates and channels, and located between a first side of a second epitaxy layer and a second side of the second epitaxy layer, the first side and the second side of the second epitaxy layer being on the first side and the second side, respectively, of the first epitaxy layer; and a metal layer on the first side of the first epitaxy layer and the first side of the second epitaxy layer.

The metal layer may be on: a top surface of the first side of the first epitaxy layer; a top surface and a bottom surface of the first side of the second epitaxy layer; and a side surface of the first epitaxy layer and the second epitaxy layer.

The metal layer may form an Ohmic contact with the first side of the first epitaxy layer and the first side of the second epitaxy layer.

The first side and the second side of the first epitaxy layer may include silicon germanium having a first concentration ration of silicon to germanium, and the first side and the second side of the second epitaxy layer includes silicon.

The first side and the second side of the first epitaxy layer may include an n-type material and the first side and the second side of the second epitaxy layer may include a p-type material.

The first side and the second side of the first epitaxy layer and the first stack of gates and channels may form a first metal-oxide semiconductor (MOS) and the first side and the second side of the second epitaxy layer and the second stack of gates and channels may form a second MOS.

The metal layer may be a metal selected from the group consisting of nickel and platinum.

The first stack of gates and channels may be configured to receive a gate voltage.

The second side of the second epitaxy layer may be configured to receive a source voltage and the second side of the first epitaxy layer may be configured to receive a drain voltage.

According to one or more embodiments, a method for fabricating a semiconductor device may include: growing the first side of the first epitaxy layer at the first side of the first stack of gates and channels, and growing the second side of the first epitaxy layer at the second side of the first stack of gates and channels; applying a sacrificial layer on the first side and the second side of the first epitaxy layer; growing the first side and the second side of the second epitaxy layer on the sacrificial layer; removing the sacrificial layer; and depositing the metal layer on the first side of the first epitaxy layer and the first side of the second epitaxy layer.

According to one or more embodiments, a method for fabricating a common output stack transistor may include: forming a first stack of gates and channels on a substrate; forming a second stack of gates and channels on the first stack of gates and channels; growing a first epitaxy layer on the substrate and adjacent to a first side and a second side of the first stack of gates and channels; applying a sacrificial layer on the first epitaxy layer; removing the sacrificial layer; growing a second epitaxy layer on the sacrificial layer and adjacent to a first side and a second side of a second stack of gates and channels; and depositing a metal layer on the first epitaxy layer and the second epitaxy layer.

The depositing the metal layer may be performed by an atomic layer deposition process, and the sacrificial layer may include silicon germanium having a concentration ratio of silicon to germanium, which is different from a concentration ratio of silicon to germanium in the first epitaxy layer.

The scope of the invention is defined by the claims, which are incorporated into this section by reference. A more complete understanding of embodiments of the invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 is a circuit diagram of an inverter that utilizes the stack transistors, according to one or more embodiments of the present disclosure.

FIGS. 2A and 2B are a cross-sectional view and a top view, respectively of a schematic of a conventional stack transistor.

FIG. 3 is a cross-sectional view of a stack transistor, according to one or more embodiments of the present disclosure.

FIGS. 4A-4E illustrate a process for fabricating the stack transistor, according to one or more embodiments of the present disclosure.

FIG. 5 is a flow diagram illustrating a process for fabricating the stack transistor according to one or more embodiments of the present disclosure.

FIG. 6 is an example system diagram of an electronic device may utilize the stack transistors, according to one or more embodiments of the present disclosure.

Embodiments of the present disclosure and their aspects and features are best understood by referring to the detailed description that follows. Unless otherwise noted, like reference numerals denote like elements throughout the attached drawings and the written description, and thus, descriptions thereof may not be repeated. In the drawings, the relative sizes of elements, layers, and regions may be exaggerated for clarity.

### DETAILED DESCRIPTION

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

With semiconductor devices, as the number of transistors placed on a chip continue to increase, space on the chip becomes a commodity. Therefore, over time, the sizes of the transistors have become smaller, and the transistors themselves are being more tightly packed on the chip resulting in chips with more densely packed transistors. One way to densely pack the transistors is to stack the transistors one on top of another instead of spreading them adjacently across the same substrate as in a planar n-channel metal-oxide silicon (NMOS) and p-channel metal-oxide silicon (PMOS). For example, the NMOS may be stacked on top of the PMOS, or the PMOS may be stacked on top of the NMOS in a 3-dimensional (3D) stack field effect transistor (3DS-FET) also referred to herein as a “stack FET” or a “stack transistor.”

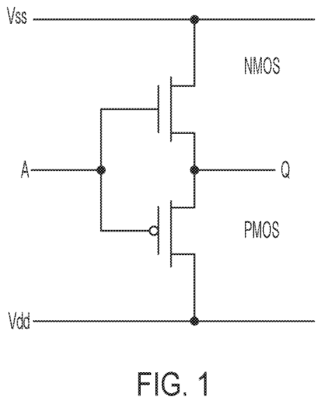

However, the stack transistor configuration faces challenges that were not inherent in planar configuration transistors. One issue faced in the stacked configuration arises when it is desired to connect the source/drain of the top tier device to the source/drain of the bottom tier device. For example, when the transistor is to be configured as an inverter, a common output is formed by coupling the source/drain of the top tier device with the source/drain of the bottom tier device. FIG. 1 is an example circuit diagram of an inverter that utilizes stack transistors. According to one or more embodiments, a complementary metal-oxide semiconductor (CMOS) inverter may be formed by electrically connecting an NMOS and a PMOS as illustrated. Here, the NMOS and the PMOS may be coupled together, a drain voltage Vdd may be connected to one electrode of the NMOS, and a source voltage Vss may be connected to one electrode of the PMOS. An input A to the inverter may be provided to the gates of the NMOS and the PMOS, and the outputs may be electrically coupling to form a common output. Accordingly, one or more embodiments of the present disclosure may be directed to processes for fabricating an inverter the uses the stack transistor configuration.

However, techniques used in related art may face challenges because the PN junction created by the NMOS and the PMOS creates a relatively high voltage drop (e.g., 0.7 V), which is unacceptable in logic circuit technologies because a voltage in the range of 0.7 V may be close to Vdd voltage. Other methods to overcome these issues may result in complex fabrication processes and issues. Accordingly, techniques for a simpler fabrication process that can guarantee reliable common output junction between the top tier device and the bottom tier device is desirable.

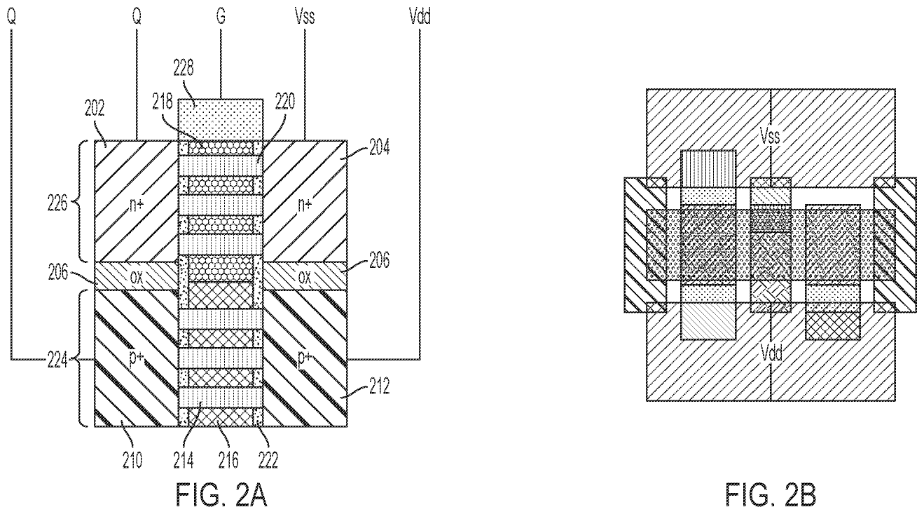

FIGS. 2A and 2B are a cross-sectional view and a top view, respectively, of a related art stack transistor. The stack transistor includes a bottom tier device 224 and a top tier device 226. The bottom tier device 224 includes a bottom p-type (e.g., p+) source/drain epitaxy layer 210, 212, a plurality of bottom gates 216, channels 214 connecting the source/drain epitaxy layer 210 on the left to the source/drain epitaxy layer 212 on the right. A spacer 222 is placed between the gates and the source/drain epitaxy layers 210, 212, and a gate cap 228 is provided on top of the stack of gates and channels 120, 118. In one or more embodiments, the spacer 222 may be made up nitride or oxide materials but is not limited thereto. Here in the present disclosure, the term “source/drain” epitaxy layer may be used to indicate that the epitaxy layer (or the epitaxial layer) may be either a source or a drain of a transistor. Accordingly, the source/drain epitaxy layer 210 on the left is spaced from the source/drain epitaxy layer 212 on the right, with the channel 214 located therebetween.

The top tier device 226 is constructed similarly to the bottom tier device 224 except that the top source/drain epitaxy layer 202, 204 is made of (or includes) an n-type material (e.g., n+). A plurality of channels 220 and a plurality of gates 218 are stacked alternatingly between the top source/drain epitaxy layer 202 at the left and the top source/drain epitaxy layer 204 at the right. Furthermore, spacers 222 are placed between the top gates 218 and the top source/drain epitaxy layers 202, 204. An oxide layer 206, 208 is formed between the top source/drain epitaxy 202, 204 and the bottom source/drain epitaxy layers 210, 212. Thus, the oxide layer 206, 208 forms a barrier therebetween and therefore results in a relatively large voltage drop across this PN junction as described earlier.

The stack transistor may be configured to operate as an inverter by connecting Vss at the top source/drain epitaxy layer 204 and Vdd at the bottom source/drain epitaxy layer 212, a gate voltage to the gate 216, 218, and the output of the inverter may be provided from the top source/drain epitaxy layer 202 and the bottom source/drain epitaxy layer 210. To have a common output inverter, the outputs from the top and the bottom source/drain epitaxy layer 202, 210 need to be connected together to form the common node. However, some difficulties may be faced when forming the common output in such conventional stack transistor. First, the oxide layer 206, 208 isolates the top and the bottom source/drain epitaxy layers, thus isolating the two epitaxies.

One method of forming the common output include utilizing a relatively long via or a trench in the device to connect a contact from the top source/drain epitaxy layer 226 with a contact from the bottom source/drain epitaxy layer 224. However, the use of a long via having a high aspect ratio may result in parasitic effects, for example increased parasitic resistance and/or increased parasitic capacitance. To overcome some of these issues, the oxide layer 206 may be removed and an Ohmic contact may be made between and along the sides of the top source/drain epitaxy layer 202 and the bottom source/drain epitaxy layer 210, according to one or more embodiments of the present disclosure.

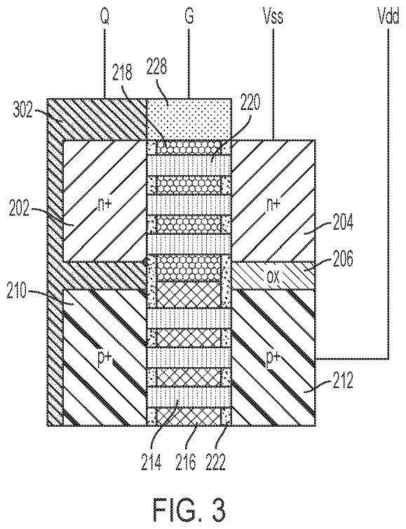

FIG. 3 is a cross-sectional view of an improved common output stack transistor according to one or more embodiments of the present disclosure. Here, the oxide layer 206 shown in FIG. 2A has been removed, for example, by etching, and a metal layer 302 is formed between the top source/drain epitaxy layer 202 and the bottom source/drain epitaxy layer 210, on top of the top source/drain epitaxy layer 202, and along the sides of the top source/drain epitaxy layer 202 and the bottom source/drain epitaxy layer 210. Accordingly, a direct connection may be formed between the top source/drain epitaxy layer 202 and the bottom source/drain epitaxy layer 210, thus avoiding the large voltage drop that resulted across the PN junction in the related art configuration. Here, the voltage drop may be negligible to none across the PN junction and the parasitic capacitance and the parasitic resistance are also reduced by orders of magnitude.

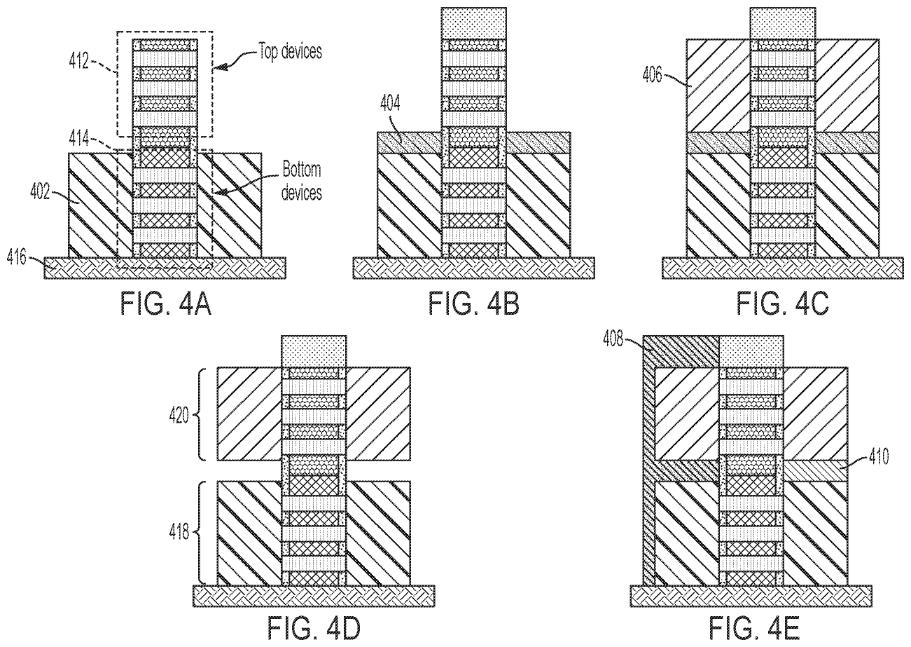

FIGS. 4A-4E illustrate a process for forming the stack transistor shown and described with reference to FIG. 3, according to one or more embodiments of the present disclosure. In one or more embodiments, the stacked gates may be made of gate metals and gate oxides including interfacial-layer (IL) oxide (e.g., SiO₂ or SiOₓ) and high-dielectric (HK) oxides. In other words, each gate layer of the stacked gates may be made of different material(s) to adjust a gate work function and threshold voltage of the device. Moreover, the composition of the gate material for the NMOS may be a different composition of gate material from the PMOS. In one or more embodiments, the stack of channels may be made of, for example, silicon or silicon germanium (SixGe1-). Accordingly, the stack of gates and the stack of channels may be stacked alternatingly, one on top of another in the manner illustrated in FIGS. 4A-4E. Furthermore, the stack of gates and channels may include any number of gates with the channels therebetween, for example three gates, as shown. For purposes of this disclosure, it may be assumed that the stacked gate and the channel layers that form the top devices 412 and the bottom devices 414 are already formed and provided according to techniques known by those having ordinary skill in the art. Thus, the steps illustrated and described with reference to FIGS. 4A-4E are directed to the processes for forming the source/drain epitaxy layers of the stack transistors and the metal layer that forms the common output.

In FIG. 4A, the gate and channel layers forming the top device 412 and the bottom device 414 are provided as mentioned above. In one or more embodiments, a substrate 416 may be provided and the gate and channel layers may be formed on the substrate. Then, according to a first step of the present disclosure, the bottom source/drain epitaxy layer 402 may be grown on the substrate 416 so that the bottom source/drain epitaxy layer 402 may be formed adjacent to the gate and channel layers of the bottom device 414. In one or more embodiments, the bottom source/drain epitaxy layer 402 may be a p-type material, thus forming a PMOS device as the bottom tier device 418 (for example, see FIG. 4D). In this case, the bottom source/drain epitaxy layer 402 may be formed using p-type material such as silicon germanium that is doped with acceptor dopants such as, for example, greater than 1×10²⁰ cm³ concentration of boron, which includes a suitable percentage of silicon and a suitable percentage of germanium.

In one or more embodiments, the top source/drain epitaxy layer 412 may be made of (e.g., includes) an n-type material, in which case an NMOS device would be formed for the top tier device 420. In this case, the top source/drain epitaxy layer 412 may be formed using n-type material such as pure silicon that is doped with a high concentration of donor dopants such as, for example greater than 1×10²⁰ cm⁻³ concentration of phosphorus or arsenic. Therefore, the percentage of germanium in the source/drain epitaxy layer 402 may be 0% when the percentage of silicon is 100%. Accordingly, while an NMOS on PMOS device is described herein the present disclosure, in one or more embodiments, the device may be a PMOS on NMOS device instead.

In FIG. 4B, after the bottom source/drain epitaxy layer 402 for the bottom tier device 418 is grown, a sacrificial layer 404 may be applied on the bottom source/drain epitaxy layer 402. In one or more embodiments, the sacrificial layer may be an oxide layer or it may be silicon germanium having a different percentage of germanium than in the material for the bottom source/drain epitaxy layer 402. For example, the respective percentages of germanium and silicon for the bottom source/drain epitaxy layer 402 (PMOS) may be 50% germanium and 50% silicon, and the respective percentages of germanium and silicon for the sacrificial layer 404 may be 20% germanium and 80% silicon. Because of the different percentages of germanium in the bottom source/drain epitaxy layer 402 and the sacrificial layer 404, selective etching may be performed on the sacrificial layer 404 without affecting (or substantively affecting) the bottom source/drain epitaxy layer 402, which will be described in more detail later. It should be noted that the percentages provided for germanium and silicon are approximate and as examples only, and that other percentages of germanium and silicon may be used as long as the percentages of the germanium and silicon (e.g., ratio of concentration of germanium to silicon) in the bottom source/drain epitaxy 402 are suitably different from the percentages of germanium and silicon (e.g., ratio of concentration of germanium to silicon) in the sacrificial layer 404 as those of ordinary skill in the art would appreciate.

In FIG. 4C, after the sacrificial layer 404 is grown on the bottom source/drain epitaxy layer 402, a top source/drain epitaxy layer 406 may now be grown on the sacrificial layer 404. Similar to the bottom source/drain epitaxy layer 402, the top source/drain epitaxy layer 406 is grown such that the top source/drain epitaxy layer 406 is formed adjacent to the gate and channel layers of the top device 412. In one or more embodiments, the top source/drain epitaxy layer 406 may be an n-type material, thus forming an NMOS device as the top tier device 420 (for example, see FIG. 4D). In this case, the top source/drain epitaxy layer 406 may be formed using n-type material such as pure silicon. In one or more embodiments, the top source/drain epitaxy layer 406 may be a p-type material, in which case a PMOS device would be formed for the top tier device 420. In this case, the top source/drain epitaxy layer 406 may be formed using p-type material such as silicon with some percentage of germanium. It should be noted that the percentage of germanium of the top source/drain epitaxy layer 406 is also different from the percentage of germanium of the sacrificial layer 404. Furthermore, when the top tier device 420 is an NMOS, the bottom tier device 418 may be a PMOS, and when the top tier device 420 is a PMOS, the bottom tier device 418 may be an NMOS. Therefore, a corresponding n-type material or p-type material should be utilized when growing the top and bottom source/drain epitaxy layers 406, 402.

In FIG. 4D, after the top source/drain epitaxy layer 406 is grown, the sacrificial layer 404 may be removed by an etching process. If the sacrificial layer 404 is made of oxide, then an etching process such as dry etching may be used to remove the oxide layer from the top and bottom source/drain epitaxy layers 406, 402. In one or more embodiments, it may be desirable (e.g., more advantageous) to apply a sacrificial layer 404 that is made of a material including a percentage of germanium because the germanium of the sacrificial layer 404 may act as a seeding layer for the top source/drain epitaxy layer 406. For example, when a seeding layer is present in the sacrificial layer 404, when the top source/drain epitaxy layer 406 is grown on top of the sacrificial layer 404, the process for growing the top source/drain epitaxy layer 406 may be performed in a much more controlled manner, which ultimately improves the quality of the top source/drain epitaxy layer 406. It should be appreciated by those having ordinary skill in the art that the term “quality” may refer to the pureness of the crystallized epitaxy of the top source/drain epitaxy layer 406. Thus, a high-quality epitaxy is one that is little to no stacking fault and/or discoloration. On the other hand, if an oxide layer is used as the sacrificial layer 404, then the oxide does not act as a seeding layer and therefore would not have features (or the benefits) realized from a germanium containing sacrificial layer 404, and therefore the top source/drain epitaxy layer 406 may suffer from a less pure (e.g., lower quality) epitaxy.

Turning back to FIG. 4D, the etching process may be a dry etching process that removes only the material containing a specific percentage of germanium. Thus, selective etching may be performed such that only the sacrificial layer 404 containing the specific percentage of germanium may be removed, and no other materials such as the top or bottom source/drain epitaxy layers 406, 402 containing a different percentage of germanium may be removed or substantively removed. In one or more embodiments, chemical etching may be performed.

In FIG. 4E, after the sacrificial layer 404 is removed, a metal layer 408 may be deposited on the top surface side, and bottom surfaces of the top source/drain epitaxy layer 406, and the top and side surface of the bottom source/drain epitaxy layer 402 as shown. In one or more embodiments, the metal may be any type of inert metal such as nickel or platinum having a high work function. The metal layer 408 may be deposited using a process such as atomic layer deposition (ALD). Processes such as ALD may be useful because of the relatively high sticking coefficient but other deposition techniques may also be utilized.

In one or more embodiments, an oxide layer 410 may be grown on the surfaces of the right side of top source/drain epitaxy layer 406 and the right side of the bottom source/drain epitaxy layer 402 to maintain the isolation of the PN junction because the right side of the top and bottom tier devices 412, 414 are connected to Vss and Vdd, respectively.

Accordingly, by surrounding the top and bottom source/drain epitaxy layers 406, 402 with the metal layer 408, the PN junction voltage drop may be reduced or avoided and the Ohmic contact resulting from the large surface area of the top and bottom source/drain epitaxy layers 406, 402 contacting the metal layer 408 prevents or reduces parasitic resistance as well. Accordingly, the common output stack transistor shown previously in FIG. 3 may be fabricated.

In one or more embodiments, the resulting common output stack transistor illustrated in FIG. 3 may have several aspects and features that are different from (e.g., advantages over) related art devices and fabrication techniques. For example, the metal layer 408 makes an Ohmic contact with a relatively large surface area of the top and bottom epitaxy layers 406, 402. As a result, output parasitic resistance may be reduced (e.g., significantly reduced by orders of magnitude) because a long via is no longer used to connect an output from one device to an output from another device (e.g., to connect the output of the bottom tier device 418 with the output of the top tier device 420). Consequently, because the parasitic resistance is now much smaller, the drive current for the transistor may also be smaller, thereby reducing power consumption.

In one or more embodiments, the cross-couple design of the contacts connecting to the top and bottom tier devices 420, 418 may be simplified because two separate contacts are not utilized to make a contact with the top and bottom tier devices 420. Instead, because the metal layer 408 creates a common output contact, only a single contact is utilized in the cross-couple design area, which in turn saves process and design challenges associated with creating two separate contacts. In addition to simplifying the design and process, the area footprint of the inverter cell formed by the stack transistor may be reduced because a via (e.g., a contact trench) need not be formed in the device. Finally, in one or more embodiments, as mentioned above, if a silicon germanium material is used for the sacrificial layer 404, then the quality of the top source/drain epitaxy layer 406 may be controlled more carefully (and/or precisely) because the silicon germanium present in the sacrificial layer 404 may act as a seeding layer. Thus, when the top source/drain epitaxy layer 406 is grown, it may be grown with more control and more precision, thus resulting in a better quality top source/drain epitaxy layer 306.

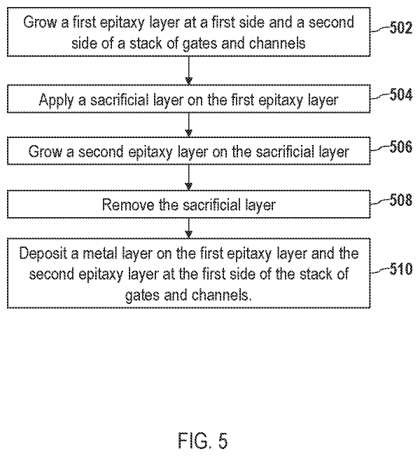

FIG. 5 is a flow diagram illustrating a process for fabricating the stack transistor according to one or more embodiments of the present disclosure. The steps described in the flow diagram generally follow the steps described above with reference to FIGS. 4A-4E. In one or more embodiments, a first epitaxy layer may be grown at a first side and a second side of a stack of gates and channels (502). The steps for processing the gates and the channels are omitted from the present disclosure but a person having ordinary skill in the art will appreciate that any suitable techniques for fabricating stacked gates and channels may be utilized. In one or more embodiments, a substrate such as a silicon substrate may be provided and the stack of gates and channels may be fabricated thereon the substrate. Then the first epitaxy layer may be grow on the substrate and adjacent to the first and second sides of the stack of gates and channels.

Next, a sacrificial layer may be applied on the first epitaxy layer (504). In one or more embodiments, the sacrificial layer may be an oxide layer or it may be a material such as silicon germanium, that includes some percentage of silicon and some percentage of germanium (e.g., a predetermine concentration ratio of silicon to germanium). In one or more embodiments, the concentration ratio of the silicon to germanium for the sacrificial layer may be different from the concentration ratio of the silicon to germanium for the first epitaxy layer.

Next, a second epitaxy layer may be grown on the sacrificial layer (506). The second epitaxy layer may be grown whether the sacrificial layer is oxide or silicon germanium. However, if the sacrificial layer is silicon germanium, the sacrificial layer may act as a seeding layer to the second epitaxy layer when it is grown at step 506. As a result, a higher quality second epitaxy layer may be grown compared to the case where the sacrificial layer is an oxide.

Next, the sacrificial layer may be removed (508) by one or more techniques known by those having ordinary skill in the art, such as, for example, etching or dry etching. When oxide is used as the sacrificial layer, a suitable etching technique for removing the oxide may be utilized. When silicon germanium is utilized as the sacrificial layer, selective etching may be performed to remove only a certain concentration ratio of silicon germanium. Accordingly, the sacrificial layer may be removed without removing (e.g., inadvertently removing) the first epitaxy layer that may be made of a material having a different concentration ratio of silicon to germanium.

After the sacrificial layer is removed, a metal layer may be deposited on the first epitaxy layer and the second epitaxy layer at the first side of the stack of gates and channels (510). Accordingly, the metal layer may form an Ohmic contact across the first epitaxy layer and the second epitaxy layer, and the Ohmic contact may form a common output from an inverter that is formed by this PMOS and NMOS (i.e., CMOS).

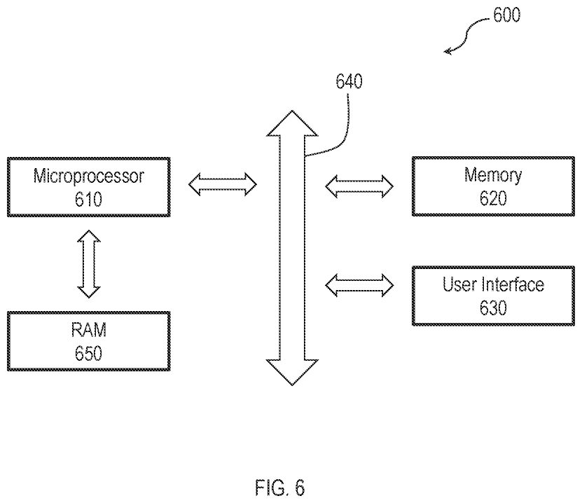

FIG. 6 illustrates a schematic block diagram of an electronic system that may implement one or more electronic devices according to one or more embodiments of the present disclosure. Referring to FIG. 6, an electronic system 600 in accordance with one or more embodiments may include a microprocessor 610, a memory 620, and a user interface 630 that perform data communication using a bus 640. The microprocessor 610 may include a central processing unit (CPU) or an application processor (AP). The electronic system 600 may further include a random access memory (RAM) 650 in communication with the microprocessor 610. The microprocessor 610 and/or the RAM 650 may be implemented in a single module or package. The user interface 630 may be used to input data to the electronic system 600, or output data from the electronic system 600. For example, the user interface 630 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 620 may store operational codes of the microprocessor 610, data processed by the microprocessor 610, or data received from an external device. The memory 620 may include a memory controller, a hard disk, or a solid state drive (SSD).

At least the microprocessor 610, the memory 620 and/or the RAM 650 in the electronic system 600 may include one or more multi-stack transistor structures described in the above embodiments.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method comprising:
growing a first epitaxy layer at a first side and a second side of a stack of gates and channels;
applying a sacrificial layer on the first epitaxy layer;
growing a second epitaxy layer on the sacrificial layer;
removing the sacrificial layer; and
depositing a metal layer on the first epitaxy layer and the second epitaxy layer at the first side of the stack of gates and channels.

2. The method of claim 1, wherein the depositing the metal layer on the first epitaxy layer and the second epitaxy layer comprises depositing the metal layer between the first epitaxy layer and the second epitaxy layer.

3. The method of claim 1, wherein the first epitaxy layer comprises silicon germanium having a first concentration ratio of silicon to germanium, and the second epitaxy layer comprises silicon.

4. The method of claim 3, wherein the sacrificial layer comprises silicon germanium having a second concentration ratio of silicon to germanium, which is different from the first concentration ratio of silicon to germanium for the first epitaxy layer.

5. The method of claim 4, wherein the sacrificial layer comprises a seeding layer for the growth of the second epitaxy layer.

6. The method of claim 4, wherein the removing the sacrificial layer further comprises dry etching to selectively remove material having the second concentration ratio of silicon to germanium.

7. The method of claim 1, wherein the first epitaxy layer is an n-type material and the second epitaxy layer is a p-type material.

8. The method of claim 1, wherein the first epitaxy layer is a p-type material and the second epitaxy layer is an n-type material.

9. A semiconductor device comprising:
a first stack of gates and channels between a first side of a first epitaxy layer and a second side of the first epitaxy layer;
a second stack of gates and channels on the first stack of gates and channels, and located between a first side of a second epitaxy layer and a second side of the second epitaxy layer, the first side and the second side of the second epitaxy layer being on the first side and the second side, respectively, of the first epitaxy layer; and
a metal layer on the first side of the first epitaxy layer and the first side of the second epitaxy layer.

10. The semiconductor device of claim 9, wherein the metal layer is on:
a top surface of the first side of the first epitaxy layer;
a top surface and a bottom surface of the first side of the second epitaxy layer; and
a side surface of the first epitaxy layer and the second epitaxy layer.

11. The semiconductor device of claim 10, wherein the metal layer forms an Ohmic contact with the first side of the first epitaxy layer and the first side of the second epitaxy layer.

12. The semiconductor device of claim 10, wherein the first side and the second side of the first epitaxy layer comprise silicon germanium having a first concentration ration of silicon to germanium, and the first side and the second side of the second epitaxy layer comprises silicon.

13. The semiconductor device of claim 10, wherein the first side and the second side of the first epitaxy layer comprise an n-type material and the first side and the second side of the second epitaxy layer comprise a p-type material.

14. The semiconductor device of claim 13, wherein the first side and the second side of the first epitaxy layer and the first stack of gates and channels form a first metal-oxide semiconductor (MOS) and the first side and the second side of the second epitaxy layer and the second stack of gates and channels form a second MOS.

15. The semiconductor device of claim 10, wherein the metal layer is a metal selected from the group consisting of nickel and platinum.

16. The semiconductor device of claim 10, wherein the first stack of gates and channels is configured to receive a gate voltage.

17. The semiconductor device of claim 16, wherein the second side of the second epitaxy layer is configured to receive a source voltage and the second side of the first epitaxy layer is configured to receive a drain voltage.

18. A method for fabricating the semiconductor device of claim 9, the method comprising:
growing the first side of the first epitaxy layer at the first side of the first stack of gates and channels, and growing the second side of the first epitaxy layer at the second side of the first stack of gates and channels;
applying a sacrificial layer on the first side and the second side of the first epitaxy layer;
growing the first side and the second side of the second epitaxy layer on the sacrificial layer;
removing the sacrificial layer; and
depositing the metal layer on the first side of the first epitaxy layer and the first side of the second epitaxy layer.

19. A method for fabricating a common output stack transistor, the method comprising:
forming a first stack of gates and channels on a substrate;
forming a second stack of gates and channels on the first stack of gates and channels;
growing a first epitaxy layer on the substrate and adjacent to a first side and a second side of the first stack of gates and channels;
applying a sacrificial layer on the first epitaxy layer;
removing the sacrificial layer;
growing a second epitaxy layer on the sacrificial layer and adjacent to a first side and a second side of a second stack of gates and channels; and
depositing a metal layer on the first epitaxy layer and the second epitaxy layer.

20. The method of claim 19,
wherein the depositing the metal layer is performed by an atomic layer deposition process, and
wherein the sacrificial layer comprises silicon germanium having a concentration ratio of silicon to germanium, which is different from a concentration ratio of silicon to germanium in the first epitaxy layer.
